(19) United States
(12) Patent Application Publication
(10) Pub. No.: US 2026/0287894 A1
(43) Pub. Date: Sep. 24, 2026

(54) AUGMENTED REALITY GLASSES DEVICE AND ITS OPTICAL DISPLAY SYSTEM

(71) Applicant: Quanta Computer Inc., Taoyuan City (TW)

(72) Inventors: Kuo-Hao LIAO, Taoyuan City (TW); Yun-Cheng LIU, Taoyuan City (TW)

(73) Assignee: Quanta Computer Inc., Taoyuan City (TW)

(21) Appl. No.: 19/231,048

(22) Filed: Jun. 6, 2025

(30) Foreign Application Priority Data
Mar. 19, 2025 (TW) 114202738

(51) Int. Cl. G02B 27/01; H10H 29/34; H10H 29/856

(52) U.S. Cl. CPC G02B 27/0172; H10H 29/34; H10H 29/856; G02B 2027/0112; G02B 2027/0178

(57) ABSTRACT

An augmented reality glasses device and its optical display system are provided. The optical display system includes a light projection lens assembly and a light projection optical engine. The light projection optical engine includes a first display module used for outputting a first light image including only a specific color light, a second display module used for outputting a second light image without the specific color light, and an optical component. The optical component is located between the light projection lens assembly and the second display module, and optically connected to the first display module and the second display module respectively so as to allow the first light image traveling in a first direction to be redirected to the light projection lens assembly, and the second light image traveling and passing through in a second direction to the light projection lens assembly.

### RELATED APPLICATIONS

This application claims priority to Taiwanese Application Serial Number 114202738 filed March 19, 2025, which is herein incorporated by reference.

### BACKGROUND

### Field of the Invention

The present disclosure relates to a display system. More particularly, the present disclosure relates to an optical display system and an augmented reality glasses device equipped with the optical display system.

### Description of Related Art

A conventional augmented reality (AR) glasses device usually has an optical engine and a light-transmitting element. The optical engine is responsible for generating and projecting images into the light-transmitting element.

However, in order to overcome the technical challenge of insufficient brightness of the optical machine, a display with larger luminous capacity and size is required, otherwise it is difficult for the AR glasses device to meet the brightness requirements suitable for use in outdoor environments.

As seen above, how to design an AR glasses device that can significantly improve display brightness while reducing material costs has become an important challenge for researchers in this technical field.

### SUMMARY

One aspect of the present disclosure is to provide an augmented reality glasses device and its optical display system for solving the difficulties mentioned above in the prior art.

In one embodiment of the present disclosure, an optical display system includes a light projection lens assembly and a light projection optical engine. The light projection optical engine includes a first display module, a second display module and an optical component. The first display module is used for outputting a first light image containing only a specific color light thereon. The second display module is used for outputting a second light image without the specific color light thereon. The optical component is located between the light projection lens assembly and the second display module, and optically connected to the first display module and the second display module, respectively, so as to allow the first light image traveling in a first direction to be redirected to the light projection lens assembly, and the second light image traveling and passing through in a second direction to the light projection lens assembly.

In one embodiment of the present disclosure, an optical display system includes a light projection lens assembly and a light projection optical engine. The light projection optical engine includes a red-light display module, a non-red-light display module and an optical component. The red-light display module is used for outputting a red-light image traveling in a first direction. The non-red-light display module is used for outputting a non-red-light image traveling in a second direction different from the first direction. The optical component is located between the light projection lens assembly and the non-red-light display module, and optically connected to the red-light display module and the non-red-light display module, so as to allow the red-light image to be redirected towards the light projection lens assembly, and allow the non-red-light image to be passed through the optical component and sent to the light projection lens assembly.

In one embodiment of the present disclosure, an augmented reality glasses device includes a spectacle frame, at least one lens, two spectacle temple arms and at least one optical display system mentioned above. The lens is located on the spectacle frame. The spectacle temple arms are arranged opposite to each other and respectively connected to the spectacle frame. The optical display system is located at one of the spectacle temple arms and faces the lens to project a full-color image onto the lens.

Thus, through the construction of the embodiments above, the augmented reality glasses device and its optical display system of this disclosure not only can achieve a balance between increasing the number of pixels and reducing the display size, but also effectively improve display brightness and reduce material costs at the same time.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

The disclosure can be more fully understood by reading the following detailed description of the embodiment, with reference made to the accompanying drawings as follows.

FIG. 1 is a schematic view of an optical display system and its optical path schematic view according to one embodiment of the present disclosure.

FIG. 2A is a front view of a first display module of FIG. 1.

FIG. 2B is a schematic view of one of the first pixels in FIG. 2A.

FIG. 3A is a front view of a second display module in FIG. 1.

FIG. 3B is a schematic view of one of the second pixels in FIG. 3A.

FIG. 4 is a perspective view of an augmented reality glasses device according to one embodiment of the present disclosure.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

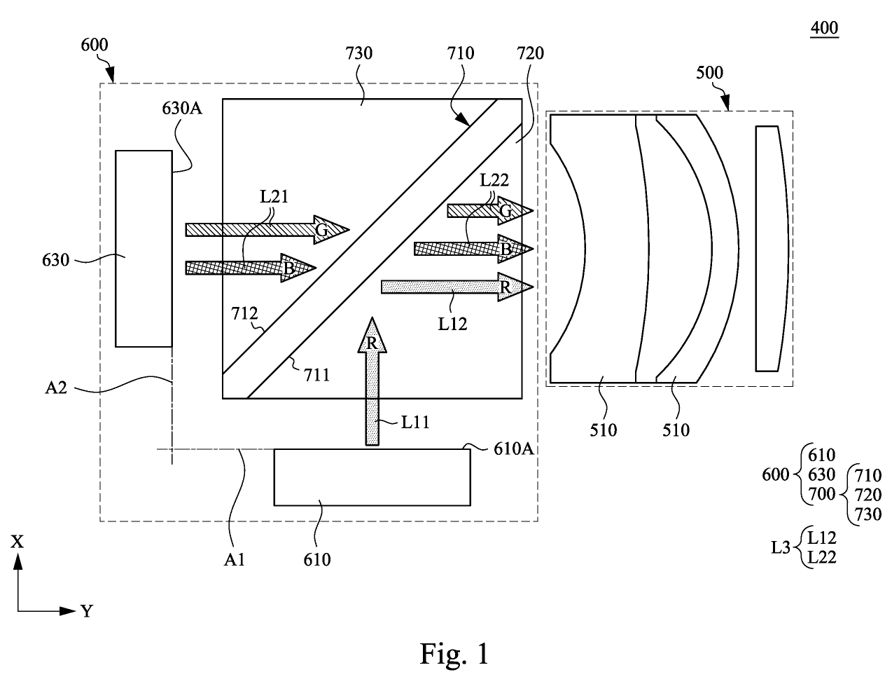

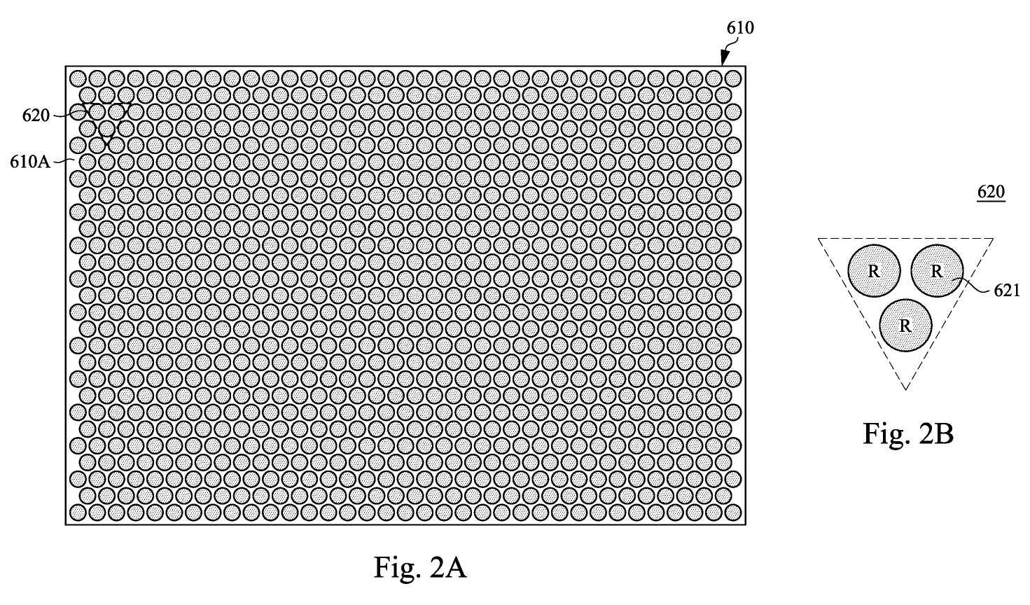

Reference is now made to FIG. 1 to FIG. 2A in which FIG. 1 is a schematic view of an optical display system 400 and its optical path schematic view according to one embodiment of the present disclosure. FIG. 2A is a front view of a first display module 610 of FIG. 1. The optical display system 400 includes a light projection lens assembly 500 and a light projection optical engine 600. The light projection optical engine 600 is responsible for generating images and projecting the images into the light projection lens assembly 500. The light projection optical engine 600 includes a first display module 610, a second display module 630 and an optical component 700. The first display module 610 and the second display module 630 are independent to each other, and the first display module 610 and the second display module 630 are two separate display panels. The first display module 610 outputs a first light image containing only a specific color light (e.g., red light R) thereon. The second display module 630 outputs a second light image without the specific color light (e.g., with blue light B and green light G but not red light R) thereon. The optical component 700 is located between the light projection lens assembly 500 and the second display module 630. The optical component 700, the light projection lens assembly 500 and the second display module 630 are with the same optical axis, and the optical component 700 is optically connected to the first display module 610 and the second display module 630, respectively.

In this way, when the first display module 610 and the second display module 630 emit lights simultaneously, i.e. the first display module 610 outputs a first light image L11 traveling in a first direction (e.g., X axis) to the optical component 700, and the second display module 630 outputs a second light image L21 traveling in a second direction (e.g., Y axis) to the optical component 700, the optical component 700 redirects the first light image L11 traveling in a first direction (e.g., X axis) to the light projection lens assembly 500 to become the first light image L12 (i.e., red light R), and allows the second light image L21 traveling in the second direction (e.g., Y axis) different from the first direction (e.g., X axis) to pass through in the second direction (e.g., Y axis) to the light projection lens assembly 500 to become the second light image L22 (i.e., blue light B and green light G), so that the first light image L12 and the second light image L22 are synthesized together in the light projection lens assembly 500 into a full-color image L3 with full RGB color. As shown in FIG. 1, for example, the first display module 610 is a red-light micro-LED display. The first display module 610 is a micro red light-emitting diode display module red light-emitting diode display module which can only output red light images. The second display module 630 is a non-red light micro light emitting diode display. The second display module 630 is a micro non-red light-emitting diode display module which can only output non-red light (e.g., blue light B and green light G) images, however, the disclosure is not limited thereto.

Thus, the design of this embodiment uses two display modules (i.e., the first display module 610 and the second display module 630) which are independent but complementary color so that the optical component 700 can combine the first light image L12 (i.e., red light R) of the first display module 610 and the second light image L22 (i.e., blue light B and green light G) of the second display module 630, which are color-complementary to each other into the full-color image L3. Such a design can achieve a balance between increasing the number of pixels and reducing the display, thereby significantly improving display brightness and reducing material costs.

In the present embodiment, in further description, two adjacent sides of the optical component 700 face the first display module 610 and the second display module 630, respectively. An imaginary extension line A1 (e.g., Y axis) of the light emitting surface 610A of the first display module 610 and an imaginary extension line A2 (e.g., X axis) of the light emitting surface 630A of the second display module 630 are orthogonal to each other. However, the present disclosure is not limited to the configuration positions of the optical component, the first display module, and the second display module.

Furthermore, the optical component 700 includes a wavelength reflector 710, a first optical prism 720 and a second optical prism 730. The wavelength reflector 710 includes a first surface 711 and a second surface 712 opposite and parallel to each other. The wavelength reflector 710 allows the first light image L11 traveling in the first direction (e.g., X axis) to be reflected by the first surface 711 to become the first light image L12 traveling in the second direction (e.g., Y axis), and allows the second light image L21 traveling in the second direction (e.g., Y axis) to be passed through the wavelength reflector 710 from the second surface 712 to the first surface 711 to become the second light image L22. In this embodiment, the wavelength reflector 710 is a red-light reflector for reflecting light with specific wavelengths (e.g., red-light R). The first optical prism 720 located between the first surface 711 of the wavelength reflector 710 and the first display module 610 is used to send the first light image L11 traveling in the first direction (e.g., X axis) to the first surface 711 of the wavelength reflector 710, and send the first light image L12 traveling in the second direction (e.g., Y axis) to the light projection lens assembly 500. The second optical prism 730 located between the second surface 712 of the wavelength reflector 710 and the second display module 630 is used to send the second light image L21 traveling in the second direction (e.g., Y axis) to the second surface 712 of the wavelength reflector 710 and pass through the he second surface 712 to become the second light image L22.

Furthermore, in a specific embodiment, the wavelength reflector 710 is sandwiched between the first optical prism 720 and the second optical prism 730, and the wavelength reflector 710 is presented as a sheet, which is installed obliquely between the first optical prism 720 and the second optical prism 730. That is, an included angle defined by one imaginary extension line (not shown) of the first surface 711 of the wavelength reflector 710 and the imaginary extension line A1 of the light emitting surface 610A of the first display module 610 is 45°, and another included angle defined by one imaginary extension line (not shown) of the second surface 712 of the wavelength reflector 710 and the imaginary extension line A2 of the light emitting surface 630A of the second display module 630 is 45°.

In addition, the light projection optical engine 600 further includes a micro display (not shown). The micro display is electrically connected to the first display module 610 and the second display module 630 for controlling the first display module 610 and the second display module 630 to output corresponding light images.

In this embodiment, as shown in FIG. 1, the light projection lens assembly 500 is composed of a plurality of lenses 510 having different functions. The synthesized full-color (RGB) image can be effectively projected outwardly through the arrangement and combination of these lenses 510. However, since these lenses 510 are well-known technologies, these lenses 510 are not described hereinafter.

FIG. 2A is a front view of a first display module 610 of FIG. 1. FIG. 2B is a schematic view of one of the first pixels 620 in FIG. 2A. In this embodiment, as shown in FIG. 2A and FIG. 2B, the first display module 610 includes a plurality of first pixels 620 which are closely arranged. Each first pixel 620 has a plurality of (e.g., three) sub-pixels. Each of the sub-pixels is, for example, a first micro-LEDs (i.e., first micro-LED) 621. In one specific embodiment, the first micro-LEDs 621 are arranged in a triangle manner. The first micro-LEDs 621 arranged in the triangle manner can maximize to utilize the entire area of the first display module 610, that is, the area occupied by all the first pixels 620 in the entire first display module 610 can be maximized.

For example, each of the first micro-LEDs 621 is a red-light micro-LED. In other words, each of the first micro-LEDs 621 only emits red lights R. The first display module 610 is only equipped with red-light micro-LEDs, and not equipped with blue or green light micro-LEDs.

It is noted, due to the material properties and physical limitations of red-light micro-LEDs, the red-light micro-LEDs will face the problem of insufficient brightness at such a small size. The main reason is that the efficiency of the materials of red-light micro-LEDs is not as good as that of the materials of green and blue-light micro-LEDs, and red-light micro-LEDs at a tiny size are more susceptible to many physical phenomena, including material efficiency, diffusion and quantum confinement effects, current squeezing effects, etc., which can lead to lower photoelectric conversion efficiency than expected, making the brightness of red light lower. In this way, the red light display module composed entirely of red light micro-LEDs can have a higher pixel density, so that the number of each of the red pixels is increased to three red light micro-LEDs (three sub-pixels) per unit area. Thus, the brightness of the red light R can be significantly improved by increasing the pixel density of the red light R, thereby compensating for its deficiency in brightness.

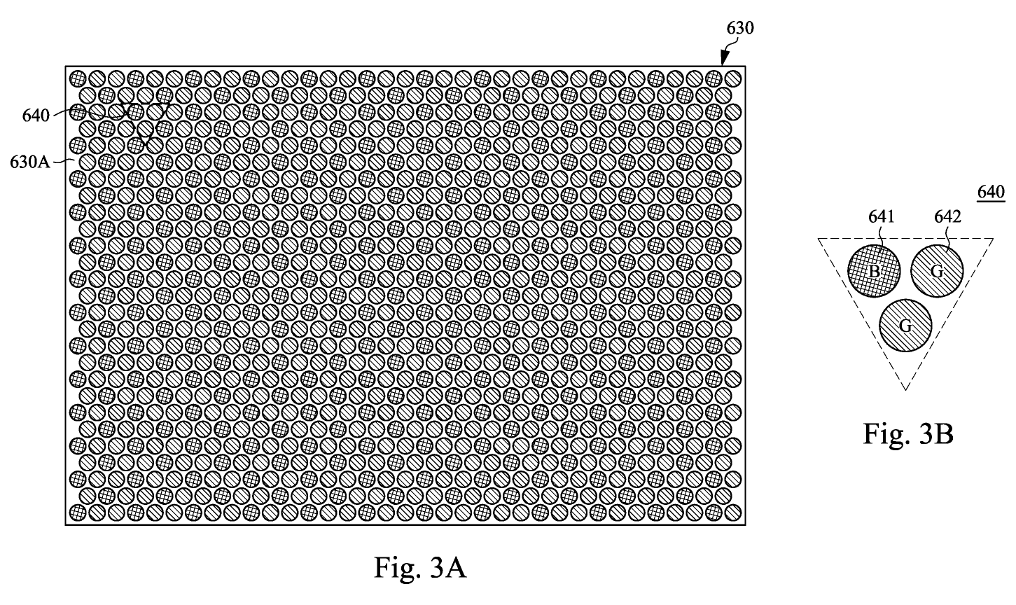

FIG. 3A is a front view of a second display module 630 in FIG. 1. FIG. 3B is a schematic view of one of the second pixels 640 in FIG. 3A. As shown in FIG. 3A and FIG. 3B, in the embodiment, the second display module 630 includes a plurality of second pixels 640, and each of the second pixels 640 has a plurality of (e.g., three) sub-pixels arranged in a triangle manner. These sub-pixels are one or more second micro light emitting diodes (i.e., second micro-LED) 641 and one or more third micro light emitting diodes (i.e., third micro-LED) 642, for example. Each of the second micro-LED 641 emits only blue light, and each of the third micro-LEDs 642 emits only green light G.

More specifically, a quantity ratio of the second micro-LEDs 641 and the third micro-LEDs 642 of each of the second pixels is 1:2.

Regarding to the prestation or arrangement of blue light B and green light G, since green light micro-LEDs play an important role in the display device and the green light G is more sensitive to the brightness perception of the naked eye. In this embodiment, the number of green light micro-LEDs per unit area in the second pixel 640 is increased to two, while the number of blue light micro-LEDs is maintained at one.

However, the invention is not limited thereto. In other embodiments, the quantity ratio of the second micro-LEDs 641 and the third micro-LEDs 642 may also be changed to 2:1 or other options.

It is noted, unlike light-emitting diodes (LEDs), Micro-light-emitting diodes (Micro-LEDs) are miniaturized the LEDs, with sizes that can be reduced to below 50μm (micrometers).

It is needed to note, it is essential to understand that as long as the emitted light images are combined to form a full-color (RGB) image, in other embodiments, the first display module may output light images containing only green light (G) or blue light (B). Complementarily, the second display module may output light images containing only the exclusion of green light (G) or blue light (B).

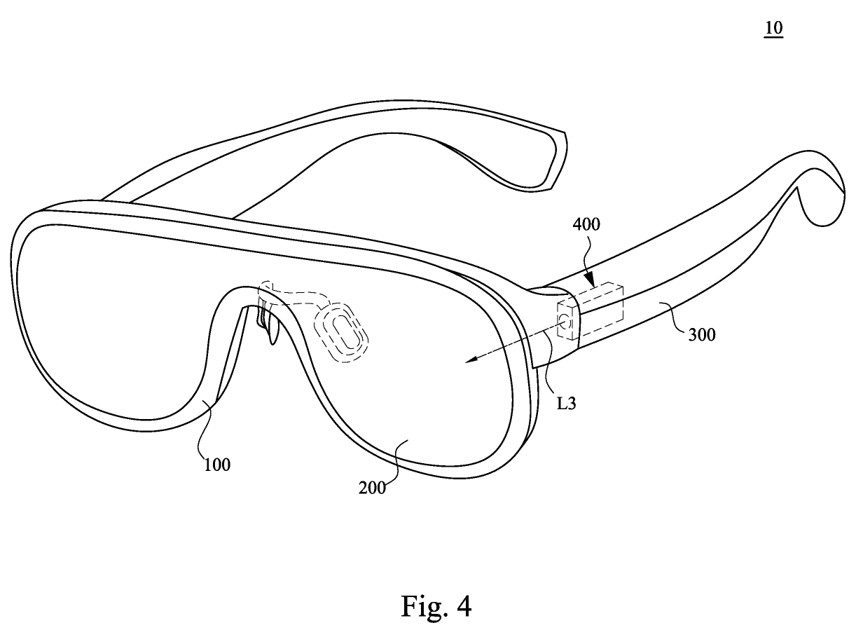

FIG. 4 is a perspective view of an augmented reality glasses device 10 according to one embodiment of the present disclosure. As shown in FIG. 3A and FIG. 3B, in the embodiment, an augmented reality glasses device 10 includes a spectacle frame 100, two lenses 200, two spectacle temple arms 300 and at least one optical display system 400 mentioned above. These lenses 200 are located on the spectacle frame 100. The spectacle temple arms 300 are arranged opposite to each other and respectively connected to the spectacle frame 100.

The optical display system 400 is located at one of the spectacle temple arms 300 and faces one of the lenses 200 through the light projection lens assembly 500 of the optical display system 400. The light projection lens assembly 500 of the optical display system 400 faces the lens 200, and projects the full-color image L3 onto the corresponding lens 200 through a light guide device (not shown in figures). The optical display system 400 can be adopted from the optical display system 400 mentioned in the embodiment (FIG. 1) above. Please refer to the text above.

However, this disclosure is not limited to this. In other embodiments, the optical display system may consist of two, allowing each lens of the augmented reality glasses device to correspond to an optical display system. Alternatively, the augmented reality glasses device may also be a monocular glass paired with this optical display system.

Thus, through the construction of the embodiments above, the augmented reality glasses device and its optical display system of this disclosure not only can achieve a balance between increasing the number of pixels and reducing the display size, but also effectively improve display brightness and reduce material costs at the same time.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An optical display system, comprising:
a light projection lens assembly; and
a light projection optical engine comprising:
a first display module that is used for outputting a first light image containing only a specific color light thereon;
a second display module that is used for outputting a second light image without the specific color light thereon; and
an optical component that is located between the light projection lens assembly and the second display module, and optically connected to the first display module and the second display module, respectively, so as to allow the first light image traveling in a first direction to be redirected to the light projection lens assembly, and the second light image traveling and passing through in a second direction to the light projection lens assembly.

2. The optical display system of claim 1, wherein the first display module comprises a plurality of first pixels, each of the first pixels includes a plurality of first micro-LEDs, and the first micro-LEDs are arranged in a triangle manner.

3. The optical display system of claim 2, wherein the second display module comprises a plurality of second pixels, each of the second pixels includes at least one second micro light emitting diode and at least one third micro light emitting diode.

4. The optical display system of claim 3, wherein each of the first micro-LEDs only emits red light, the at least one second micro light emitting diode only emits blue light, and the at least one third micro light emitting diode only emits green light.

5. The optical display system of claim 4, wherein a quantity ratio of the at least one second micro light emitting diode and the at least one third micro light emitting diode of each of the second pixels is 1:2.

6. The optical display system of claim 1, wherein the first display module and the second display module are two separate display panels.

7. The optical display system of claim 1, wherein the optical component comprises:
a wavelength reflector having a first surface and a second surface opposite to each other for allowing the first light image traveling in the first direction to be reflected by the first surface of the wavelength reflector to move towards the second direction, and allowing the second light image traveling in the second direction to pass through the wavelength reflector in a direction from the second surface to the first surface;
a first optical prism located between the first surface of the wavelength reflector and the first display module; and
a second optical prism located between the second surface of the wavelength reflector and the second display module.

8. The optical display system of claim 7, wherein the wavelength reflector is sandwiched between the first optical prism and the second optical prism.

9. The optical display system of claim 7, wherein the wavelength reflector is a red-light reflector.

10. An optical display system, comprising:
a light projection lens assembly; and
a light projection optical engine comprising:
a red-light display module that is used for outputting a red-light image traveling in a first direction;
a non-red-light display module that is used for outputting a non-red-light image traveling in a second direction different from the first direction; and
an optical component that is located between the light projection lens assembly and the non-red-light display module, and optically connected to the red-light display module and the non-red-light display module, so as to allow the red-light image to be redirected towards the light projection lens assembly, and allow the non-red-light image to be passed through the optical component and sent to the light projection lens assembly.

11. The optical display system of claim 10, wherein the red-light display module comprises a plurality of first pixels, each of the first pixels includes a plurality of first micro-LEDs, and the first micro-LEDs are arranged in a triangle manner.

12. The optical display system of claim 10, wherein the non-red-light display module comprises a plurality of second pixels, each of the second pixels includes at least one second micro light emitting diode and at least one third micro light emitting diode, the at least one second micro light emitting diode only emits blue light, and the at least one third micro light emitting diode only emits green light.

13. The optical display system of claim 12, wherein a quantity ratio of the at least one second micro light emitting diode and the at least one third micro light emitting diode of each of the second pixels is 1:2.

14. The optical display system of claim 10, wherein the red-light display module and the non-red-light display module are two separate display panels.

15. The optical display system of claim 10, wherein the optical component comprises:
a wavelength reflector having a first surface and a second surface opposite to each other for allowing the red-light image traveling in the first direction to be redirected by the first surface of the wavelength reflector to move towards the second direction, and allowing the non-red-light image traveling in the second direction to pass through the wavelength reflector in a direction from the second surface to the first surface;
a first optical prism located between the first surface of the wavelength reflector and the red-light display module; and
a second optical prism located between the second surface of the wavelength reflector and the non-red-light display module.

16. The optical display system of claim 15, wherein the wavelength reflector is sandwiched between the first optical prism and the second optical prism.

17. The optical display system of claim 15, wherein the wavelength reflector is a red-light reflector.

18. An augmented reality glasses device, comprising:
a spectacle frame;
at least one lens located on the spectacle frame;
two spectacle temple arms arranged opposite to each other and respectively connected to the spectacle frame; and
at least one optical display system of claim 1 located at one of the spectacle temple arms and facing the at least one lens for projecting a full-color image onto the at least one lens.
